(19) United States
(12) Patent Application Publication
(10) Pub. No.: US 2024/0215159 A1
(43) Pub. Date: Jun. 27, 2024

(54) CIRCUIT BOARD AND MANUFACTURING METHOD THEREOF

(71) Applicant: SAMSUNG ELECTRO-MECHANICS CO., LTD., Suwon-si (KR)

(72) Inventors: Sang-min Lee, Suwon-si (KR); Youngil Cho, Suwon-si (KR)

(73) Assignee: SAMSUNG ELECTRO-MECHANICS CO., LTD., Suwon-si (KR)

(21) Appl. No.: 18/131,019

(22) Filed: Apr. 5, 2023

(30) Foreign Application Priority Data
Dec. 26, 2022 (KR) 10-2022-0184350

(51) Int. Cl. H05K 1/03; H05K 1/11; H05K 3/00; H05K 3/10

(52) U.S. Cl. CPC H05K 1/0353; H05K 1/111; H05K 1/115; H05K 3/0017; H05K 3/103; H05K 2201/0939; H05K 2201/099

(57) ABSTRACT

A circuit board according to an embodiment includes: a first insulating layer that does not include a reinforcing material; a conductive pad that protrudes above a surface of the first insulating layer, and a second insulating layer that is disposed below the first insulating layer and includes a reinforcing material. A corner of the conductive pad has a curved shape.

### CROSS-REFERENCE TO RELATED APPLICATION

This application claims priority to and the benefit of Korean Patent Application No. 10-2022-0184350 filed in the Korean Intellectual Property Office on Dec. 26, 2022, the entire contents of which are incorporated herein by reference.

### TECHNICAL FIELD

The present disclosure relates to a circuit board and a manufacturing method thereof.

### BACKGROUND

Recently, a system in package (SIP) has been used to implement a high-performance central processing unit (CPU) by bundling two or more ICs into one package to operate as a single chip. Since a memory is mounted together on one circuit board, a silicon interposer is applied to the SIP. Accordingly, a size of the circuit board increases so that a defect due to warpage is likely to occur.

In addition, a thin package is required in the high-performance central processing unit (CPU), and a coreless substrate without a core member having a predetermined thickness is used for this purpose. Since the coreless substrate does not have the core member, the coreless substrate may be formed thin while forming more layers when the coreless substrate is compared with a circuit board having the same thickness, but the defect due to warpage is likely to occur.

When the package is assembled, the defect due to warpage that occurs in the coreless substrate includes a crack that occurs in a bump when a die and the bump are connected, a crack that occurs in a via layer due to thermal stress, a solder bridge where solder balls are shorted, or the like.

The above information disclosed in this Background section is only for enhancement of understanding of the background of the disclosure, and therefore it may contain information that does not form the prior art that is already known in this country to a person of ordinary skill in the art.

### SUMMARY

Embodiments are to provide a circuit board and a manufacturing method thereof capable of minimizing a defect due to warpage such as bending, twisting, or the like.

However, problems to be solved by the embodiments are not limited to the above-described problem and may be variously extended in a range of technical ideas included in the embodiments.

A circuit board according to an embodiment includes: a first insulating layer; a conductive pad that protrudes above a surface of the first insulating layer; and a second insulating layer that includes a material different from the first insulating layer, is disposed below the first insulating layer, and includes a reinforcing material. A corner of the conductive pad has a curved shape.

A portion of the conductive pad may be buried in the first insulating layer.

The circuit board may further include: a first via layer disposed at the first insulating layer; first circuit wiring connected to the first via layer; a second via layer disposed at the second insulating layer; and second circuit wiring connected to the second via layer. The conductive pad may be connected to the first via layer.

The corner of the conductive pad having the curved shape may be an upper corner of the conductive pad, and each of a corner of the first circuit wiring and a corner of the second circuit wiring may have an angular shape.

A radius of curvature of the corner of the conductive pad may be greater than a radius of curvature of a corner of the first circuit wiring or a radius of curvature of a corner of the second circuit wiring.

The circuit board may further include a solder resist layer that is disposed below the second insulating layer and has an opening overlapping the second circuit wiring.

The circuit board may further include: a first auxiliary pad covering the conductive pad; and a second auxiliary pad covering a surface of the second circuit wiring overlapping the opening.

Each of the first auxiliary pad and the second auxiliary pad may include a plating layer.

A minimum diameter of the second via layer may be greater than a minimum diameter of the first via layer.

The first insulating layer may include a silica filler, the second insulating layer may include a silica filler and the reinforcing material, and the reinforcing material may include a glass cloth.

The first insulating layer may not include the reinforcing material.

The corner of the conductive pad having the curved shape may protrude from the first insulating layer, and a radius of curvature of the corner of the conductive pad protruding from the first insulating layer may be greater than a radius of curvature of a corner of the conductive pad embedded in the first insulating layer.

A manufacturing method of a circuit board according to an embodiment includes: forming a conductive pad on a carrier substrate; forming a first insulating layer that covers the conductive pad on the carrier substrate; forming a second insulating layer that includes a reinforcing material on the first insulating layer; separating the carrier substrate from the first insulating layer; etching a surface of the first insulating layer to make the conductive pad protrude above the surface of the first insulating layer; and processing a corner of the conductive pad to make the corner of the conductive pad into a curved shape.

The manufacturing method may further include: forming a first via layer penetrating the first insulating layer; forming first circuit wiring connected to the first via layer on the first insulating layer; forming a second via layer penetrating the second insulating layer; and forming second circuit wiring connected to the second via layer on the second insulating layer.

A minimum diameter of the second via layer may be larger than a minimum diameter of the first via layer.

The manufacturing method may further include: forming a solder resist layer having an opening overlapping the second circuit wiring on the second insulating layer; and simultaneously forming a first auxiliary pad covering the conductive pad and a second auxiliary pad covering a surface of the second circuit wiring overlapping the opening using a plating process.

The manufacturing method may further include turning over the first insulating layer and the second insulating layer separated from the carrier substrate.

An upper corner of the conductive pad may be formed to have a curved shape.

A circuit board according to an embodiment includes: a first insulating layer; and a conductive pad including a portion protruding from the first insulating layer and another portion embedded in the first insulating layer. A corner of the portion of the conductive pad protruding from the first insulating layer has a radius of curvature greater than that of a corner of the another portion of the conductive pad embedded in the first insulating layer.

The circuit board may further include: a second insulating layer disposed below the first insulating layer and including a reinforcing material; a first via disposed in the first insulating layer; first circuit wiring connected to the conductive pad through the first via; a second via disposed in the second insulating layer; and second circuit wiring connected to the first circuit wiring through the second via.

The radius of curvature of the corner of the portion of the conductive pad protruding from the first insulating layer may be greater than a radius of curvature of a corner of the first circuit wiring or a radius of curvature of a corner of the second circuit wiring.

The circuit board may further include a solder resist layer disposed below the second insulating layer and having opening overlapping the second circuit wiring.

The circuit board may further include: a first auxiliary pad covering the conductive pad; and a second auxiliary pad disposed in the opening to cover the second circuit wiring.

A minimum diameter of the second via may be greater than a minimum diameter of the first via.

According to the embodiments, some insulating layers of a coreless substrate may include a reinforcing material to prevent warpage of the coreless substrate in one direction.

In addition, since an upper corner of a conductive pad protruding from the coreless substrate has a curved shape, a defect such as a crack or the like in the conductive pad may be prevented even when warpage occurs in the coreless substrate.

In addition, diameters of some via layers penetrating some insulating layers including the reinforcing material may be formed larger than diameters of other via layers penetrating other insulating layers not including the reinforcing material, so that it is possible to prevent a defect such as a crack or the like from occurring in some via layers by stress concentrated in some insulating layers.

As described above, since reliability of a circuit board including the coreless substrate may be improved, thinning of a package may be improved.

It is obvious that an effect of the embodiments is not limited to the above-described effect, and may be variously extended without departing from the spirit and scope of the present disclosure.

### BRIEF DESCRIPTION OF THE DRAWINGS

FIG. 1 is a cross-sectional view of a circuit board according to an embodiment.

FIG. 2 is a cross-sectional view of a state in which a chip is attached to the circuit board of FIG. 1.

FIGS. 3 to 9 are cross-sectional views sequentially illustrating a manufacturing method of a circuit board according to an embodiment.

FIG. 10 is a cross-sectional view of a circuit board according to another embodiment.

FIG. 11 is a cross-sectional view illustrating a step of a manufacturing method of a circuit board according to another embodiment.

### DETAILED DESCRIPTION OF THE EMBODIMENTS

The present disclosure will be described more fully hereinafter with reference to the accompanying drawings, in which embodiments of the disclosure are shown. As those skilled in the art would realize, the described embodiments may be modified in various different ways, all without departing from the spirit or scope of the present disclosure.

In order to clearly describe the present disclosure, parts or portions that are irrelevant to the description are omitted, and identical or similar constituent elements throughout the specification are denoted by the same reference numerals.

Further, the accompanying drawings are provided only in order to allow embodiments disclosed in the present specification to be easily understood and are not to be interpreted as limiting the spirit disclosed in the present specification, and it is to be understood that the present disclosure includes all modifications, equivalents, and substitutions without departing from the scope and spirit of the present disclosure.

Further, in the drawings, the size and thickness of each element are arbitrarily illustrated for ease of description, and the present disclosure is not necessarily limited to those illustrated in the drawings. In the drawings, the thickness of layers, films, panels, regions, etc., are exaggerated for clarity. In the drawings, for ease of description, the thicknesses of some layers and areas are exaggerated.

It will be understood that when an element such as a layer, film, region, area, or substrate is referred to as being “on” or “above” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

In addition, unless explicitly described to the contrary, the word “comprise” and variations such as “comprises” or “comprising” will be understood to imply the inclusion of stated elements but not the exclusion of any other elements.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

Furthermore, throughout the specification, “connected” does not only mean when two or more elements are directly connected, but also when two or more elements are indirectly connected through other elements, and when they are physically connected or electrically connected, and further, it may be referred to by different names depending on a position or function, and may also be referred to as a case in which respective parts that are substantially integrated are linked to each other.

Hereinafter, various embodiments and variations will be described in detail with reference to the drawings.

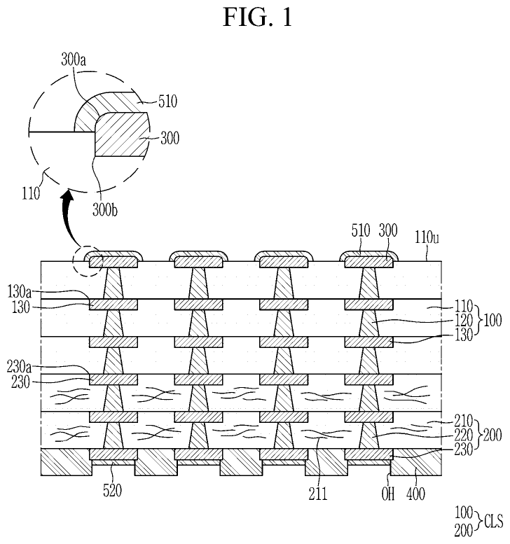

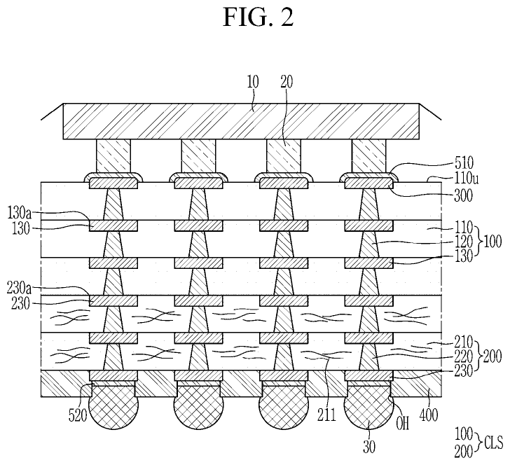

Referring to FIGS. 1 and 2, a circuit board according to an embodiment will be described.

FIG. 1 is a cross-sectional view of the circuit board according to the embodiment, and FIG. 2 is a cross-sectional view of a state in which a chip is attached to the circuit board of FIG. 1.

As shown in FIG. 1, the circuit board according to the embodiment includes at least one first layer portion (or at least one first layer unit) 100, at least one second layer portion (or at least one second layer unit) 200, a conductive pad 300, a solder resist layer 400, a first auxiliary pad 510, and a second auxiliary pad 520. Hereinafter, for convenience of explanation, the first layer portion 100 and the second layer portion 200 are collectively defined as a coreless substrate CLS.

The first layer portion 100 may be disposed above or on the second layer portion 200. The first layer portion 100 may include a first insulating layer 110, a first via layer 120, and first circuit wiring 130.

The first insulating layer 110 may include a thermosetting resin such as epoxy resin, polyimide, or the like, or a thermoplastic resin such as polyethylene (PE), polycarbonate (PC), polyvinyl chloride (PVC), or the like. For example, the first insulating layer 110 may include an Ajinomoto build-up film (ABF) or the like. The ABF may be a polymeric epoxy film available from Ajinomoto Fine-Techno Company, Inc. The first insulating layer 110 may include a silica filler.

The first via layer 120 may pass through the first insulating layer 110, and may be connected to the first circuit wiring 130. The first via layer 120 may include a conductive material such as copper (Cu), aluminum (Al), silver (Ag), tin (Sn), gold (Au), nickel (Ni), lead (Pb), titanium (Ti), an alloy thereof, or the like. A side surface of the first via layer 120 may be formed to be tapered. That is, the side surface of the first via layer 120 may have an obtuse angle with respect to a plane parallel to a surface of the first insulating layer 110.

The first circuit wiring 130 may be disposed below the first insulating layer 110, and may transmit an electrical signal. The first circuit wiring 130 may be disposed in various patterns. The first circuit wiring 130 may include a conductive material such as copper (Cu), aluminum (Al), silver (Ag), tin (Sn), gold (Au), nickel (Ni), lead (Pb), titanium (Ti), an alloy thereof, or the like.

In the present embodiment, three first layer portions 100 are stacked, but the present disclosure is not necessarily limited thereto, and various numbers of first layer portions 100 may be stacked.

The second layer portion 200 may include a second insulating layer 210, a second via layer 220, and second circuit wiring 230.

The second insulating layer 210 may include a thermosetting resin such as epoxy resin, polyimide, or the like, or a thermoplastic resin such as polyethylene (PE), polycarbonate (PC), polyvinyl chloride (PVC), or the like. For example, the second insulating layer 210 may include an Ajinomoto build-up film (ABF) or the like. The second insulating layer 210 may include a silica filler.

In addition, the second insulating layer 210 may further include a reinforcing material 211 capable of preventing warpage (or deformation) due to a physical external force. The reinforcing material 211 may include a glass cloth or the like. As described above, since the second insulating layer 210 includes the reinforcing material 211, warpage in one direction of the coreless substrate CLS due to thermal stress or the like during a manufacturing process may be prevented.

The second via layer 220 may pass through the second insulating layer 210, and may be connected to the second circuit wiring 230. The second via layer 220 may include a conductive material such as copper (Cu), aluminum (Al), silver (Ag), tin (Sn), gold (Au), nickel (Ni), lead (Pb), titanium (Ti), an alloy thereof, or the like. A side surface of the second via layer 220 may be formed to be tapered. That is, the side surface of the second via layer 220 may have an obtuse angle with respect to a plane parallel to a surface of the second insulating layer 210.

The second circuit wiring 230 may be disposed below the second insulating layer 210, and may transmit an electrical signal. The second circuit wiring 230 may be disposed in various patterns. The second circuit wiring 230 may include a conductive material such as copper (Cu), aluminum (Al), silver (Ag), tin (Sn), gold (Au), nickel (Ni), lead (Pb), titanium (Ti), an alloy thereof, or the like.

In the present embodiment, two second layer portions 200 are stacked, but the present disclosure is not necessarily limited thereto, and various numbers of second layer portions 200 may be stacked.

The conductive pad 300 may be connected to the first circuit wiring 130 through the first via layer 120, and may protrude above a surface 110u of the first insulating layer 110. In addition, a lower surface of the conductive pad 300 may be buried within the first insulating layer 110.

The conductive pad 300 may be bonded to a solder bump 20 attached to a die 10 to transmit an electrical signal to the die 10. The conductive pad 300 may include a conductive material such as copper (Cu), gold (Au), silver (Ag), a double layer of nickel (Ni) and gold (Au), or the like.

In this case, an upper corner 300a of the conductive pad 300 protruding above the surface 110u of the first insulating layer 110 has a curved shape, and a lower corner 300b buried within the first insulating layer 110 may have an angular shape. Accordingly, a radius of curvature of the upper corner 300a of the conductive pad 300 may be greater than a radius of curvature of the lower corner 300b.

In addition, unlike a corner 130a of the first circuit wiring 130 and a corner 230a of the second circuit wiring 230 having an angular shape, the upper corner 300a of the conductive pad 300 has a curved shape. That is, the radius of curvature of the upper corner 300a of the conductive pad 300 may be greater than a radius of curvature of the corner 130a of the first circuit wiring 130 or a radius of curvature of the corner 230a of the second circuit wiring 230.

Therefore, since stress is not concentrated on the protruding upper corner 300a of the conductive pad 300 even when warpage occurs in the coreless substrate CLS, occurrence of a defect such as a crack or the like in the conductive pad 300 may be prevented.

The solder resist layer 400 may be disposed below the second insulating layer 210, and may cover the second circuit wiring 230. The solder resist layer 400 may have an opening (or an opening portion) OH overlapping the second circuit wiring 230 on a plane. The solder resist layer 400 may include an insulating material such as a solder resist or the like.

The first auxiliary pad 510 may cover the conductive pad 300. The first auxiliary pad 510 may include a plating layer. The plating layer may be formed by an electroless plating process, and may include gold (Au), silver (Ag), nickel (Ni), palladium (Pd), or the like.

The second auxiliary pad 520 may cover a surface of the second circuit wiring 230 overlapping the opening OH of the solder resist layer 400. The second auxiliary pad 520 may be adjacent to the second insulating layer 210. The second auxiliary pad 520 may include a plating layer. The plating layer is formed by a plating process and may include gold (Au), silver (Ag), nickel (Ni), palladium (Pd), or the like.

The second insulating layer 210 adjacent to the second auxiliary pad 520 includes the reinforcing material 211 to minimize warpage of the coreless substrate CLS so that solder balls 30 bonded to the second auxiliary pad 520 are prevented from being shorted each other.

As described above, in the circuit board according to the embodiment, the second insulating layer 210 of the coreless substrate CLS may include the reinforcing material 211, and the upper corner 300a of the protruding conductive pad 300 may have a curved shape. As a result, even when warpage occurs in the coreless substrate CLS, occurrence of a defect such as a crack or the like in the conductive pad 300, the second via layer 220, or the like may be minimized.

In one example, the first insulating layer 110 of the coreless substrate CLS may not include the reinforcing material 211, although the present disclosure is not limited thereto.

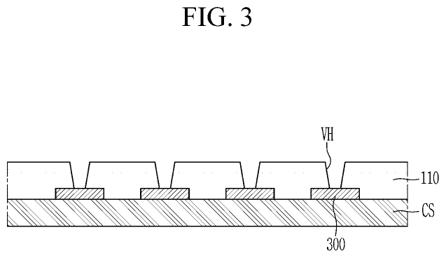

Referring to FIGS. 3 to 9 along with FIGS. 1 and 2, a manufacturing method of a circuit board according to an embodiment will be described in detail.

FIGS. 3 to 9 are cross-sectional views sequentially illustrating the manufacturing method of the circuit board according to the embodiment.

As shown in FIG. 3, the conductive pad 300 is formed on a carrier substrate CS. The carrier substrate CS may be a substrate that may be separated from the conductive pad 300 in a subsequent process. The carrier substrate CS may include a copper foil stacking plate or the like. Then, the first insulating layer 110 covering the conductive pad 300 is formed on the carrier substrate CS. The first insulating layer 110 may not include the reinforcing material 211. Then, a via hole VH overlapping the conductive pad 300 is formed at the first insulating layer 110 using a photolithography process (or a photo etching process).

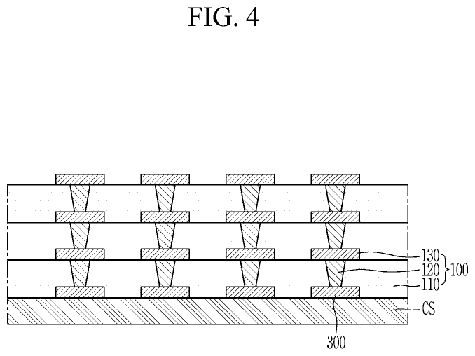

As shown in FIG. 4, the first via layer 120 is formed by filling the via hole VH of the first insulating layer 110. In this case, the side surface of the first via layer 120 may be formed to be inversely tapered. Then, the first circuit wiring 130 connected to the first via layer 120 is formed on the first insulating layer 110. Here, the first insulating layer 110, the first via layer 120, and the first circuit wiring 130 together constitute the first layer portion 100. Then, the first layer portion 100 may be repeatedly stacked. In the present embodiment, three first layer portions 100 are formed, but the present disclosure is not necessarily limited thereto, and various numbers of first layer portions 100 may be formed.

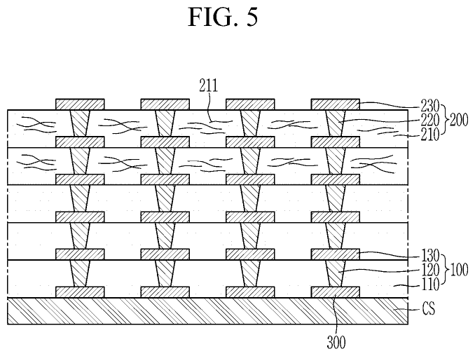

As shown in FIG. 5, the second insulating layer 210 is formed on the first layer portion 100. The second insulating layer 210 may include the reinforcing material 211. Then, the second via layer 220 passing through the second insulating layer 210 is formed using a photolithography process. In this case, the side surface of the second via layer 220 may be formed to be inversely tapered. Then, the second circuit wiring 230 connected to the second via layer 220 is formed on the second insulating layer 210. Here, the second insulating layer 210, the second via layer 220, and the second circuit wiring 230 together constitute the second layer portion 200. Then, the second layer portion 200 may be repeatedly stacked. In the present embodiment, two second layer portions 200 are formed, but the present disclosure is not necessarily limited thereto, and various numbers of second layer portions 200 may be formed.

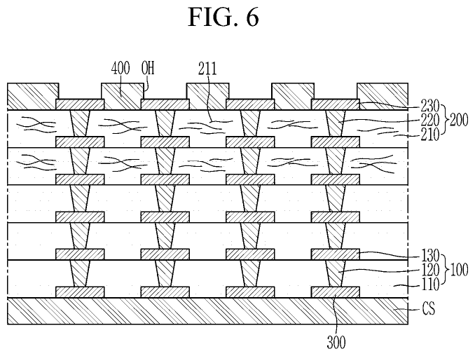

As shown in FIG. 6, the solder resist layer 400 having the opening OH overlapping the second circuit wiring 230 is formed on the second layer portion 200. The opening OH may be formed by performing processes such as exposure, curing, development, and the like on the solder resist layer 400 using a mask.

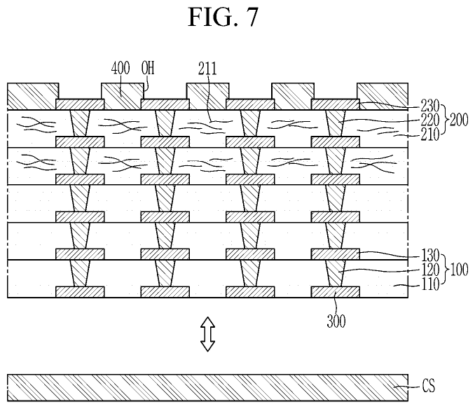

As shown in FIG. 7, the carrier substrate CS is separated from the first layer portion 100. That is, the carrier substrate CS is separated from the first insulating layer 110 of the first layer portion 100.

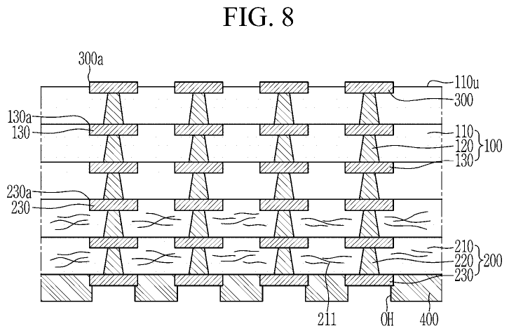

As shown in FIG. 8, the coreless substrate CLS including the first layer portion 100 and the second layer portion 200 is turned over. Then, a surface of the first insulating layer 110 of the uppermost first layer portion 100 among the plurality of first layer portions 100 is etched to have the conductive pad 300 protrude above the surface 110u of the first insulating layer 110 of the first layer portion 100. In this case, the upper corner 300a of the conductive pad 300 may have an angular shape.

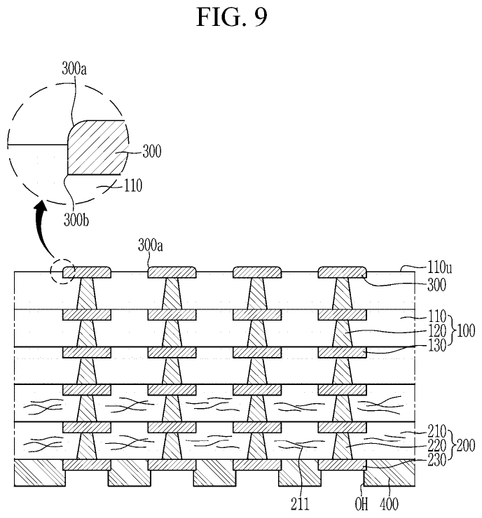

As shown in FIG. 9, the upper corner 300a of the conductive pad 300 is processed to make the upper corner 300a of the conductive pad 300 into a curved shape. In this case, the upper corner 300a of the conductive pad 300 may be formed into a curved shape using a photolithography process, a laser process, or the like.

As shown in FIG. 1, the first auxiliary pad 510 covering the conductive pad 300 is formed, and at the same time, the second auxiliary pad 520 covering the surface of the second circuit wiring 230 overlapping the opening OH of the second insulating layer 210 is formed. The first auxiliary pad 510 and the second auxiliary pad 520 may be formed using a surface treatment process for respectively applying electrical signals to the conductive pad 300 and the second circuit wiring 230. The surface treatment process may include an electroless plating process such as electroless nickel electroless palladium immersion gold (ENEPIG), electroless nickel immersion gold (ENIG), or the like. The ENEPIG is a plating process in which electroless palladium is disposed between electroless nickel and substitution gold to prevent nickel corrosion during substitution gold plating that is a problem of the ENIG.

As described above, since the second insulating layer 210 of the coreless substrate CLS includes the reinforcing material 211 in the embodiment, it is possible to prevent warpage in one direction of the coreless substrate CLS.

In addition, the upper corner 300a of the conductive pad 300 protruding from the coreless substrate CLS may have a curved shape so that occurrence of a defect such as a crack or the like in the conductive pad 300 is prevented even when warpage occurs in the coreless substrate CLS.

On the one hand, in the above embodiment, a minimum diameter of the first via layer and a minimum diameter of the second via layer are the same, but another embodiment in which the minimum diameter of the second via layer is larger than the minimum diameter of the first via layer is also possible.

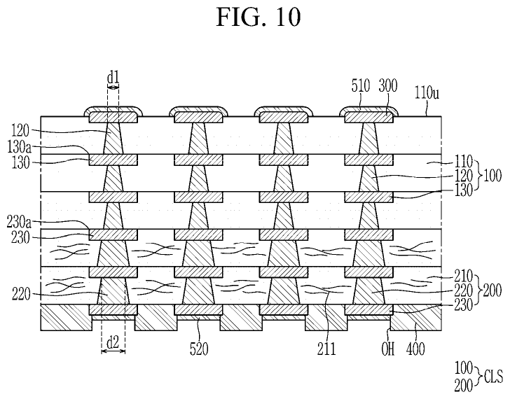

Hereinafter, a circuit board according to another embodiment will be described in detail with reference to FIG. 10.

FIG. 10 is a cross-sectional view of the circuit board according to the other embodiment.

The other embodiment shown in FIG. 10 is substantially the same as the embodiment shown in FIG. 1 except that a diameter of the second via layer is larger than a diameter of the first via layer, and thus a repeated description thereof is omitted.

As shown in FIG. 10, the circuit board according to the other embodiment includes the at least one first layer portion (or the at least one first layer unit) 100, the at least one second layer portion (or the at least one second layer unit) 200, the conductive pad 300, the solder resist layer 400, the first auxiliary pad 510, and the second auxiliary pad 520.

Here, a minimum diameter d2 of the second via layer 220 of the second layer portion 200 may be greater than a minimum diameter d1 of the first via layer 120 of the first layer portion 100.

As described above, the minimum diameter d2 of the second via layer 220 penetrating the second insulating layer 210 including the reinforcing material 211 may be formed larger than the minimum diameter d1 of the first via layer 120 penetrating the first insulating layer 110 not including the reinforcing material 211, so that a defect such as a crack or the like is prevented from occurring in the second via layer 220 by stress concentrated in the second insulating layer 210.

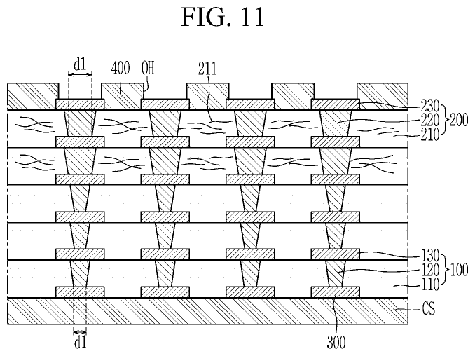

Referring to FIG. 11 together with FIG. 10, a manufacturing method of a circuit board according to another embodiment will be described in detail.

FIG. 11 is a cross-sectional view illustrating a step of the manufacturing method of the circuit board according to the other embodiment.

The other embodiment shown in FIG. 11 is substantially the same as the embodiment shown in FIGS. 3 to 9 except that the minimum diameter of the second via layer is larger than the minimum diameter of the first via layer, and thus a repeated description thereof is omitted.

As shown in FIG. 11, the conductive pad 300 is formed on the carrier substrate CS. Then, the first layer portion 100 including the first insulating layer 110, the first via layer 120, and the first circuit wiring 130 is formed on the carrier substrate CS. Then, the second layer portion 200 including the second insulating layer 210, the second via layer 220, and the second circuit wiring 230 is formed on the first layer portion 100. In this case, the minimum diameter d2 of the second via layer 220 of the second layer portion 200 may be formed greater than the minimum diameter d1 of the first via layer 120 of the first layer portion 100. As described above, the minimum diameter d2 of the second via layer 220 penetrating the second insulating layer 210 including the reinforcing material 211 may be formed larger than the minimum diameter d1 of the first via layer 120 penetrating the first insulating layer 110 not including the reinforcing material 211, so that a defect such as a crack or the like is prevented from occurring in the second via layer 220 by stress concentrated in the second insulating layer 210. Then, the solder resist layer 400 having the opening OH overlapping the second circuit wiring 230 is formed on the second layer portion 200.

Then, as shown in FIG. 10, the carrier substrate CS is separated from the first layer portion 100, and the coreless substrate CLS including the first layer portion 100 and the second layer portion 200 is turned over. Then, the conductive pad 300 protrudes above the surface 110u of the first insulating layer 110 of the first layer portion 100. Then, the upper corner 300a of the conductive pad 300 is processed to make the upper corner 300a of the conductive pad 300 into a curved shape. Then, the first auxiliary pad 510 covering the conductive pad 300 is formed, and at the same time, the second auxiliary pad 520 covering the surface of the second circuit wiring 230 overlapping the opening OH of the second insulating layer 210 is formed.

While this disclosure has been described in connection with what is presently considered to be practical embodiments, it is to be understood that the disclosure is not limited to the disclosed embodiments, but, on the contrary, is intended to cover various modifications and equivalent arrangements included within the spirit and scope of the appended claims.

What is claimed is:

1. A circuit board comprising:
a first insulating layer;
a conductive pad that protrudes above a surface of the first insulating layer; and
a second insulating layer that includes a material different from the first insulating layer, is disposed below the first insulating layer, and includes a reinforcing material,
wherein a corner of the conductive pad has a curved shape.

2. The circuit board of claim 1, wherein a portion of the conductive pad is buried in the first insulating layer.

3. The circuit board of claim 1, further comprising:
a first via layer disposed at the first insulating layer;
first circuit wiring connected to the first via layer;
a second via layer disposed at the second insulating layer; and
second circuit wiring connected to the second via layer,
wherein the conductive pad is connected to the first via layer.

4. The circuit board of claim 3, wherein the corner of the conductive pad having the curved shape is an upper corner of the conductive pad, and each of a corner of the first circuit wiring and a corner of the second circuit wiring has an angular shape.

5. The circuit board of claim 3, wherein a radius of curvature of the corner of the conductive pad is greater than a radius of curvature of a corner of the first circuit wiring or a radius of curvature of a corner of the second circuit wiring.

6. The circuit board of claim 3, further comprising a solder resist layer that is disposed below the second insulating layer and has an opening overlapping the second circuit wiring.

7. The circuit board of claim 6, further comprising:
a first auxiliary pad covering the conductive pad; and
a second auxiliary pad covering a surface of the second circuit wiring overlapping the opening.

8. The circuit board of claim 7, wherein each of the first auxiliary pad and the second auxiliary pad includes a plating layer.

9. The circuit board of claim 3, wherein a minimum diameter of the second via layer is greater than a minimum diameter of the first via layer.

10. The circuit board of claim 1, wherein the first insulating layer includes a silica filler, the second insulating layer includes a silica filler and the reinforcing material, and the reinforcing material includes a glass cloth.

11. The circuit board of claim 1, wherein the first insulating layer does not include the reinforcing material.

12. The circuit board of claim 1, wherein the corner of the conductive pad having the curved shape protrudes from the first insulating layer, and
a radius of curvature of the corner of the conductive pad protruding from the first insulating layer is greater than a radius of curvature of a corner of the conductive pad embedded in the first insulating layer.

13. A manufacturing method of a circuit board, comprising:
forming a conductive pad on a carrier substrate;
forming a first insulating layer that covers the conductive pad on the carrier substrate;
forming a second insulating layer that includes a reinforcing material on the first insulating layer;
separating the carrier substrate from the first insulating layer;
etching a surface of the first insulating layer to have the conductive pad protrude above the surface of the first insulating layer; and
processing a corner of the conductive pad to make the corner of the conductive pad into a curved shape.

14. The manufacturing method of claim 13, further comprising:
forming a first via layer penetrating the first insulating layer;
forming first circuit wiring connected to the first via layer on the first insulating layer;
forming a second via layer penetrating the second insulating layer; and
forming second circuit wiring connected to the second via layer on the second insulating layer.

15. The manufacturing method of claim 14, wherein a minimum diameter of the second via layer is formed larger than a minimum diameter of the first via layer.

16. The manufacturing method of claim 14, further comprising:
forming a solder resist layer having an opening overlapping the second circuit wiring on the second insulating layer; and
simultaneously forming a first auxiliary pad covering the conductive pad and a second auxiliary pad covering a surface of the second circuit wiring overlapping the opening using a plating process.

17. The manufacturing method of claim 13, wherein an upper corner of the conductive pad is formed to have a curved shape.

18. The manufacturing method of claim 13, wherein the first insulating layer does not include the reinforcing material.

19. A circuit board comprising:
a first insulating layer; and
a conductive pad including a portion protruding from the first insulating layer and another portion embedded in the first insulating layer,
wherein a corner of the portion of the conductive pad protruding from the first insulating layer has a radius of curvature greater than that of a corner of the another portion of the conductive pad embedded in the first insulating layer.

20. The circuit board of claim 19, further comprising:
a second insulating layer disposed below the first insulating layer and including a reinforcing material;
a first via disposed in the first insulating layer;
first circuit wiring connected to the conductive pad through the first via;
a second via disposed in the second insulating layer; and
second circuit wiring connected to the first circuit wiring through the second via.

21. The circuit board of claim 20, wherein the radius of curvature of the corner of the portion of the conductive pad protruding from the first insulating layer is greater than a radius of curvature of a corner of the first circuit wiring or a radius of curvature of a corner of the second circuit wiring.

22. The circuit board of claim 20, further comprising a solder resist layer disposed below the second insulating layer and having opening overlapping the second circuit wiring.

23. The circuit board of claim 22, further comprising:
a first auxiliary pad covering the conductive pad; and
a second auxiliary pad disposed in the opening to cover the second circuit wiring.

24. The circuit board of claim 20, wherein a minimum diameter of the second via is greater than a minimum diameter of the first via.

25. The circuit board of claim 20, wherein the first insulating layer does not include the reinforcing material.
